(19) United States
(12) Patent Application Publication
(10) Pub. No.: US 2004/0169258 A1
(43) Pub. Date: Sep. 2, 2004

(54) Semiconductor wafer having separation groove on insulating film on dicing line region and its manufacturing method

(75) Inventor: Toshitsune Iijima, Tama-shi (JP)

Correspondence Address: FOLEY AND LARDNER, SUITE 500, 3000 K STREET NW, WASHINGTON, DC, 20007, US

(73) Assignee: KABUSHIKI KAISHA TOSHIBA

(21) Appl. No.: 10/732,304

(22) Filed: Dec. 11, 2003

(30) Foreign Application Priority Data
Dec. 12, 2002 (JP) 2002-360324

(51) Int. Cl. H01L 23/544; H01L 21/30

(52) U.S. Cl. 257/620; 438/458

(57) ABSTRACT

A semiconductor wafer includes a plurality of element-forming regions, a dicing line region and an insulating film. The dicing line region separates the element-forming regions from each other. The insulating film covers the element-forming regions and the dicing line region. The insulating film insulating film is formed of multi-layered insulating layers which insulate respective wiring layers of a multi-layer form. A separation region is formed at least in a portion of the insulating film located on the dicing line region, so that the separation region separates the insulating film on the dicing line region from the insulating film on the element-forming regions.

### CROSS-REFERENCE TO RELATED APPLICATIONS

This application is based upon and claims the benefit of priority from the prior Japanese Patent Application No. 2002-360324, filed Dec. 12, 2002, the entire contents of which are incorporated herein by reference.

### BACKGROUND OF THE INVENTION

1. Field of the Invention

The present invention relates to an insulating film formed of multi-layered insulating layers which insulate respective wiring layers of a multi-layer form, and more particularly to the structure of an insulating film formed of multi-layered insulating layers provided on a dicing line area, and a method for manufacturing this insulating film.

2. Description of the Related Art

There is a demand for currently available microprocessors to process a much greater volume of data at higher speed. So far, reducing the size of transistors has been an important goal in microprocessor design. Recently, however, the resistance-capacitance (RC) delay (the delay due to the resistance of the wires connecting transistors, and the capacitance of the insulating material between the wires) has also become a problem.

More specifically, there is a need to change the wiring material from aluminum (Al) to copper (Cu), and the insulation material from a silicon oxide film to a film having a lower relative dielectric constant. However, since low-relative-dielectric-constant insulating films generally have a porous structure to secure their low dielectric constant, they have much lower mechanical and adhesion strengths than silicon oxide films. Therefore, when, for example, a semiconductor wafer having the low-dielectric-constant insulating film formed thereon is diced into individual chips, the insulating film may be easily peeled off. In the prior art, a means for preventing a semiconductor wafer from fragmenting when the wafer is diced into individual chips is known (see, for example, Jpn. Pat. Appln. KOKAI Publication No. 6-5701, page 2, FIG. 1; Jpn. Pat. Appln. KOKAI Publication No. 9-306872, page 3, FIG. 1).

Test pads for electrical test and position aligning marks, formed of a conductive wiring material, are formed on the dicing line region. The conductive wiring is also covered with the insulating film covering the element-forming regions and the dicing line region. When the semiconductor wafer is diced into individual chips, the insulating film is also diced simultaneously. A low-dielectric-constant insulating film is generally used as the insulating film. Low-dielectric-constant insulating films have low mechanical and adhesion strengths. Hence, when the semiconductor wafer is diced into individual chips, the insulating film may be easily peeled off. When the peeling once occurred at the insulating film on the dicing line region, the insulating film on the element-forming regions will be peeled off accordingly, resulting in destruction of the semiconductor elements formed in the element-forming regions.

### BRIEF SUMMARY OF THE INVENTION

According to an aspect of the invention, there is provided a semiconductor wafer comprising:

a plurality of element-forming regions;

a dicing line region which separates the element-forming regions from each other; and

an insulating film which covers the element-forming regions and the dicing line region, the insulating film being formed of multi-layered insulating layers which insulate respective wiring layers of a multi-layer form,

wherein a separation region is formed at least in a portion of the insulating film located on the dicing line region, the separation region separating the insulating film on the dicing line region from the insulating film on the element-forming regions.

According to another aspect of the invention, there is provided a method of producing a semiconductor wafer, comprising:

forming a plurality of element-forming regions separated from each other by a dicing line region, the element-forming regions each having a semiconductor element;

covering the element-forming regions and the dicing line region with an insulating film, the insulating film being formed of multi-layered insulating layers which insulate respective wiring layers of a multi-layer form; and

forming a separation region at least in a portion of the insulating film located on the dicing line region, the separation region separating the insulating film on the dicing line region from the insulating film on the element-forming regions.

According to a further aspect of the invention, there is provided a semiconductor chip comprising:

an element-forming region in which a semiconductor element is formed;

a dicing line region which surrounds the element-forming regions; and

an insulating film which covers the element-forming region and the dicing line region, the insulating film being formed of multi-layered insulating layers which insulate respective wiring layers of a multi-layer form,

wherein a separation region is formed at least in a portion of the insulating film located on the dicing line region, the separation region separating the insulating film on the dicing line region from the insulating film on the element-forming region.

### BRIEF DESCRIPTION OF THE SEVERAL VIEWS OF THE DRAWING

FIG. 1 is a plan view illustrating a semiconductor wafer before an insulating film is provided thereon;

FIG. 2 is a plan view of a semiconductor wafer according to a first embodiment of the present invention, illustrating an insulating film provided on a dicing line region;

FIG. 3 is a sectional view taken along line III-III in FIG. 2;

FIG. 4 is a sectional view taken along line IV-IV in FIG. 2;

FIG. 5 is a plan view illustrating a semiconductor chip obtained by dicing the semiconductor wafer of FIG. 2;

FIG. 6 is a sectional view illustrating the semiconductor chip of FIG. 5;

FIG. 7 is a plan view illustrating another semiconductor chip obtained by dicing the semiconductor wafer of FIG. 2;

FIG. 8 is a sectional view illustrating the semiconductor chip of FIG. 7;

FIG. 9 is a plan view illustrating a further semiconductor chip obtained by dicing the semiconductor wafer of FIG. 2;

FIG. 10 is a sectional view illustrating the semiconductor chip of FIG. 9;

FIG. 11 is a plan view illustrating an element-forming region (chip-forming region), a dicing line region, and separation regions formed in the portion of an insulating film provided on the dicing line region;

FIG. 12 is a plan view illustrating an element-forming region (chip-forming region), a dicing line region, and separation regions formed in the portion of an insulating film provided on the dicing line region;

FIG. 13 is a plan view of a semiconductor wafer according to a second embodiment of the present invention, illustrating an insulating film provided on a dicing line region; and

FIG. 14 is a plan view of a semiconductor wafer according to a third embodiment of the present invention, illustrating an insulating film provided on a dicing line region.

### DETAILED DESCRIPTION OF THE INVENTION

Embodiments of the invention will be described in detail with reference to the accompanying drawings.

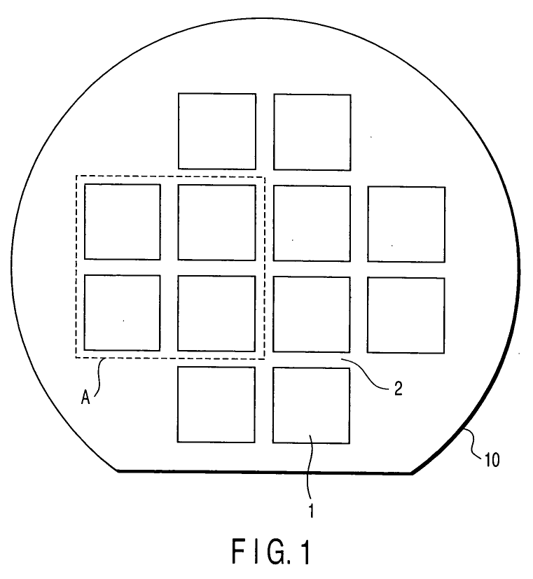

Referring first to FIGS. 1 to 12, a first embodiment of the present invention will be described.

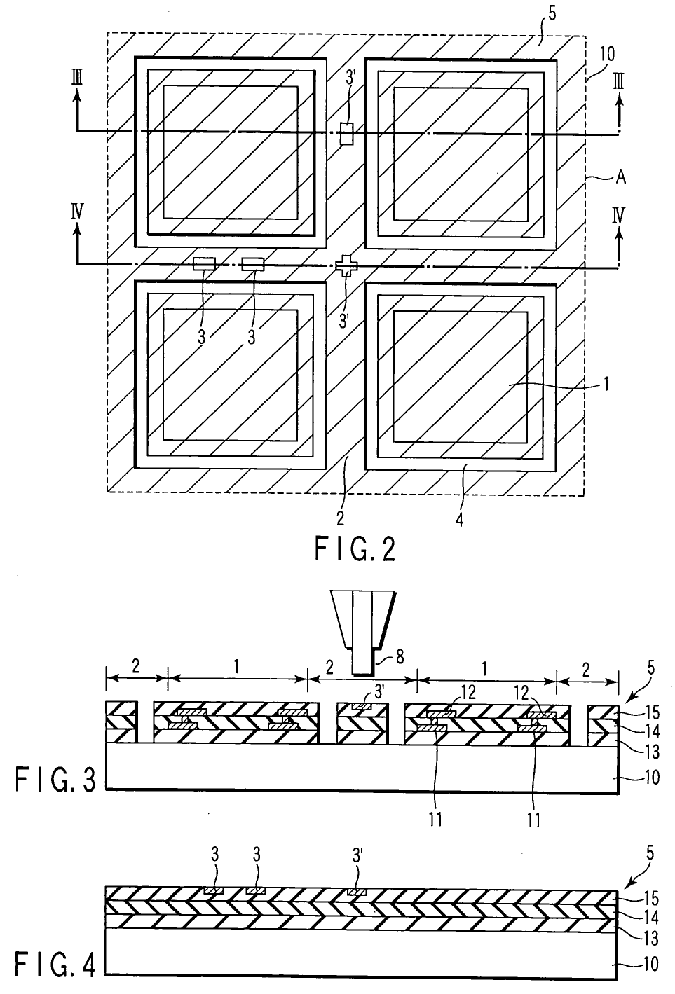

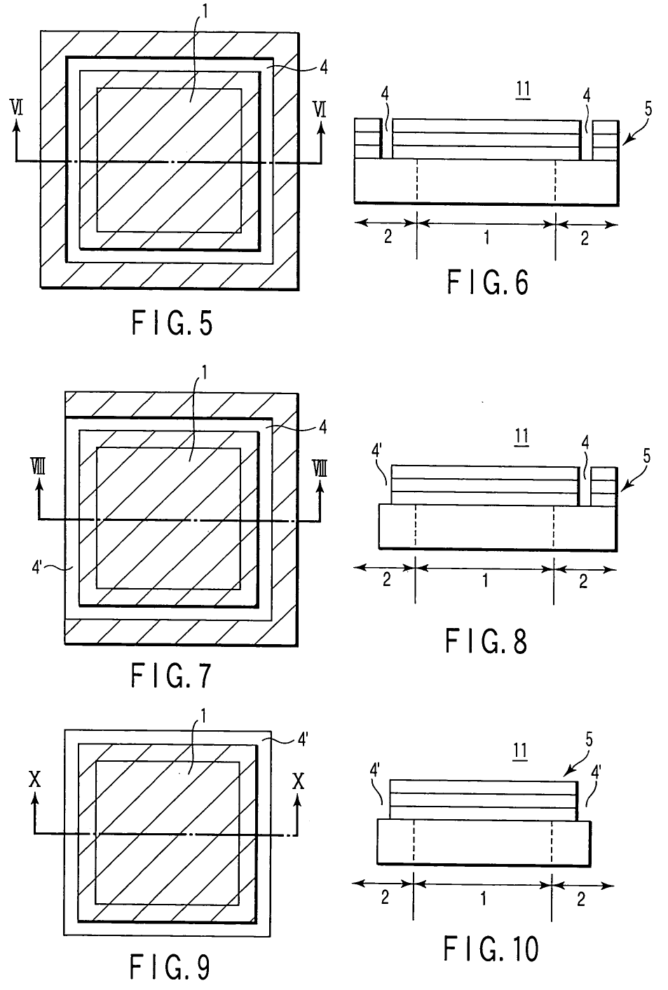

FIG. 1 is a plan view illustrating a semiconductor wafer before an insulating film is provided thereon. FIG. 2 is a plan view illustrating part of a semiconductor wafer according to the first embodiment of the present invention. FIGS. 3 and 4 are sectional views taken along lines III-III and IV-IV in FIG. 2, respectively. FIGS. 5, 7 and 9 are plan views illustrating semiconductor chips obtained by dicing the semiconductor wafer of FIG. 2, and FIGS. 6, 8 and 10 are sectional views illustrating the semiconductor chips and taken along lines VI-VI, VIII-VIII, and X-X, respectively. FIGS. 11 and 12 are plan views of semiconductor wafers each illustrating an element-forming region (chip-forming region), a dicing line region, and a separation region formed in the insulating film provided on the dicing line region.

As seen from FIG. 1, a semiconductor wafer 10 formed of, for example, silicon comprises a plurality of element-forming regions 1 and a dicing line region 2 that defines the regions 1. The element-forming regions 1 are provided with semiconductor elements and are used as individual semiconductor chips after they are separated. To divide the semiconductor wafer 10 into a plurality of semiconductor chips, a cut is made in the wafer 10 along the dicing line region 2. Along this cut, the wafer 10 is then divided into semiconductor chips. A cut is made, for example, by a diamond cutter (scribing), by melting a wafer surface with a laser beam (laser radiation), or by forming a cut groove utilizing high-speed rotation of a blade (sawing for dicing).

An insulating film 5 is provided on the semiconductor wafer 10 with semiconductor elements. The insulating film 5 is formed of multi-layered insulating layers 13, 14, and 15 (FIG. 3) which insulate respective wiring layers 11 and 12 (FIG. 3) of a multi-layer form. The insulating film 5 covers both the element-forming regions and dicing region.

In the embodiment, a low-relative-dielectric-constant insulating film (generally called Low-k film) is mainly used as the insulating film. As the low-relative-dielectric-constant insulating film, a silicon oxide film doped with fluorine F (relative dielectric constant: 3.4 to 3.7) is widely used, which has a lower relative dielectric constant than a silicon oxide film (relative dielectric constant: 3.9 to 4.1).

The low-relative-dielectric-constant insulating film can be formed of two types of material. One type of material has its relative dielectric constant lowered by lowering the density of a silicon oxide film (relative dielectric constant: 3.9 to 4.1). This type of material is, for example, MSQ (methyl silsesquioxane: CH₃-SiO_{1.5} (relative dielectric constant: 2.7-3.0)), HSQ (hydrogen silsesquioxane: H-SiO_{1.5} (relative dielectric constant: 3.5-3.8)), porous HSQ (H-SiOₓ (relative dielectric constant: 2.2)), porous MSQ (CH₃-SiO_{1.5} (relative dielectric constant: 2.0-2.5)), etc. When a low-relative-dielectric-constant insulating film is formed using the one type material, coating is employed. This type of material also includes organic silica (CH₃-SiOₓ (relative dielectric constant: 2.5 to 3.0)). When a low-relative-dielectric-constant insulating film is formed using organic silica (CH₃-SiOₓ (relative dielectric constant: 2.5 to 3.0)), plasma CVD is employed. Low-relative-dielectric-constant insulating films called Low-k films have a relative dielectric constant less than 3.9.

The other type of material is an organic type of material having a low polarizability. This type of material is, for example, PTFE (polytetrafluoroethylene (relative dielectric constant: 2.1)), PAE (polyarylether (relative dielectric constant: 2.7 to 2.9)), porous PAE (relative dielectric constant: 2.6 to 3.3)), BCB (benzocyclobutene: (relative dielectric constant: 2.6 to 3.3)), etc. To form a low-relative-dielectric-constant insulating film using these materials, coating, such as rotation coating, is utilized.

FIG. 2 is a plan view illustrating the portion (region A) of the semiconductor wafer 10 provided with an insulating film 5 formed of multi-layered insulating layers which insulate respective wiring layers of a multi-layer form. The region A corresponds to the region enclosed by the broken line in FIG. 1. The insulating film 5 is formed on the element-forming regions 1 and dicing line region 2. Test pads 3, position aligning marks 3′, etc., formed of Al or Cu, are exposed on the portion of the insulating film 5 provided on the dicing line region 2. These test pads and marks may be coated with a protection film. Further, separation regions (separation grooves 4 in the embodiment) that surround the respective element-forming regions 1 are formed on the portion of the insulating film 5 provided on the dicing line region 2. The separation region separates the insulating film on the dicing line region from the insulating film on the element-forming regions. In this embodiment, the separation regions 4 completely surround the respective peripheries of the element-forming regions 1.

FIGS. 3 and 4 are sectional views of the semiconductor wafer 10 shown in FIG. 2, illustrating the state in which the insulating film 5 covers the semiconductor wafer surface. FIG. 3 taken along line III-III of FIG. 2 shows the separation grooves 4 formed in the portion of the insulating film 5 provided on the dicing line region 2. Further, FIG. 3 shows the position aligning mark 3′ of Al or Cu buried in the insulating film 5 on the dicing line region 2. Also, FIG. 3 shows multi-layered wiring layers 11 and 12 and the insulating film 5 being formed of insulating layers 13, 14 and 15 insulating the wiring layers 11 and 12. FIG. 4 taken along line IV-IV in FIG. 2 shows test pad 3 and the position aligning mark 3′. After finishing the required processes, the semiconductor wafer 10 is divided in units of element-forming regions, thereby forming a plurality of semiconductor chips.

The semiconductor wafer 10 can be divided using the above-mentioned methods. In the case of FIG. 3, sawing for dicing using a blade 8 is employed. Specifically, the blade 8, which is in the form of a metal disk with diamond particles fixed to its periphery by a nickel-based binder, is moved along the dicing line while it is rotated at high speed, thereby forming grooves in the surface of the semiconductor wafer 10. FIG. 3 shows the case where grooves extending in the direction perpendicular to the surface of the figure are formed. As shown in FIG. 3, the blade is moved along substantially the center of the dicing line region, thereby forming grooves extending along substantially the center of the dicing line region. After that, the wafer is divided into individual chips by cutting it along the grooves.

Since the dicing line region is wider than the width of the blade, when the semiconductor wafer is divided in units of element-forming regions, each resultant semiconductor chip is larger than each element-forming region. In other words, each semiconductor chip 11 comprises the element-forming region 1 in which a semiconductor element such as an integrated circuit has been formed and dicing line region 2 that surrounds the region 1, and the dicing line region 2 serves as a margin region (in which no semiconductor element is formed). As shown in FIGS. 5 to 10, the semiconductor chip of this embodiment has an insulating film structure different from the conventional one. In the semiconductor chip 16 shown in FIGS. 5 and 6, the separation groove 4 is formed in the portion of the insulating film 5 located on the dicing line region 2. In other words, the separation groove 4 is provided on the dicing line region 2 around the four sides of each semiconductor chip. This groove is very effective. FIG. 6 is similar to FIG. 3, however, the multi-layered wiring layers are omitted for simplification. Also in FIG. 6, the hatching to the insulating film 5 is omitted for simplification.

Since the force exerted upon the periphery is absorbed by the separation groove, almost no stress occurs in the insulating film 5 on the element-forming region 1. Accordingly, it seldom occurs that the insulating film 5 on the element-forming region 1 is damaged to thereby damage the wiring layers.

During movement, the blade may deviate from the correct position, therefore the groove is not always formed along the center of the dicing line region. In an extreme case, the groove may significantly deviate from the correct position, thereby cutting off the edge portion of the insulating film that defines the groove.

In the semiconductor chip 16 shown in FIGS. 7 and 8, an edge portion of the insulating film on the dicing line region is cut off, and therefore no grooves are formed there. As a result of cut off, a margin region 4′ (where no insulating film is formed) is defined. At the other three edges, like the FIGS. 5 and 6, the insulating film 5 and separation groove are provided, as is shown in FIGS. 7 and 8. As described above, at the three edges in which the respective separation grooves exist, the force exerted upon the periphery is absorbed by the separation grooves, almost no stress occurs in the insulating film 5 on the element-forming region 1. Accordingly, it seldom occurs that the insulating film 5 on the element-forming region 1 is damaged to thereby damage the wiring layers. In the case of FIGS. 7 and 8, the three edges have respective separation groove. Instead, two or one edge may have a separation groove. FIG. 8 is similar to FIG. 3, however, the multi-layered wiring layers are omitted for simplification. Also in FIG. 8, the hatching to the insulating film 5 is omitted for simplification.

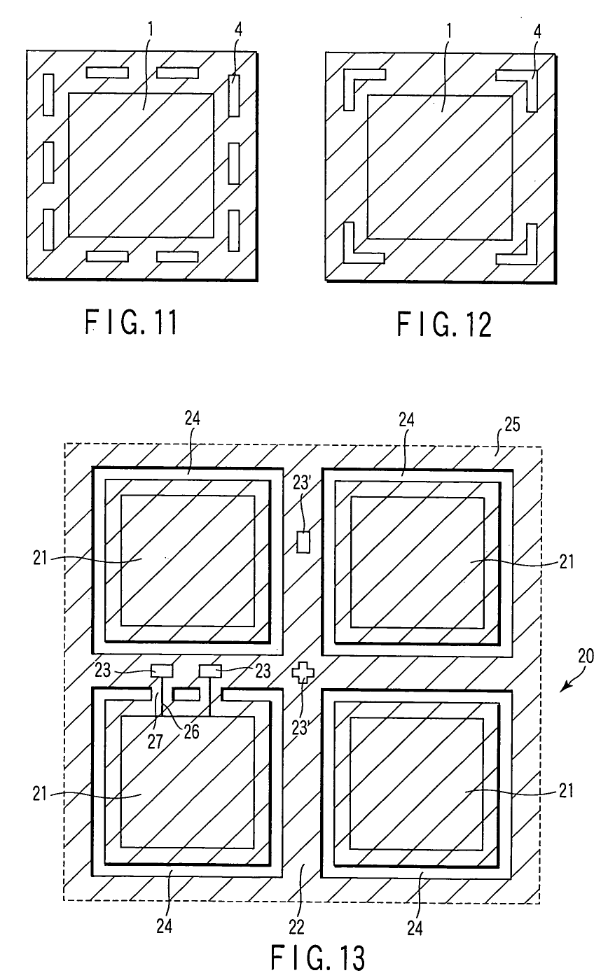

In the semiconductor chip 16 shown in FIGS. 9 and 10, the four edge portions of the insulating film of the dicing line region are cut off, and therefore no grooves are formed. As a result of cut off, margin regions 4′ where no insulating film is formed are defined. FIG. 10 is similar to FIG. 3, however, the multi-layered wiring layers are omitted for simplification. Also in FIG. 10, the hatching to the insulating film 5 is omitted for simplification.

A description will now be given of a method for forming the insulating film on a semiconductor wafer with semiconductor elements.

Firstly, an insulating film is formed on a semiconductor wafer so that it covers element-forming regions and a dicing line region formed on the wafer, the dicing line region surrounding the element-forming regions. The insulating film is formed of multi-layered insulating layers which insulate respective wiring layers of a multi-layer form. After forming the insulating film, a separation region (separation groove in this embodiment) is formed in the portion of the insulating film located on the dicing line region so that the insulating film located on the dicing line region is separated from the insulating film located on the element-forming regions. The separation groove is formed by chemically etching that portion of the insulating film where the separation grooves are to be formed after the insulation film is provided on the semiconductor wafer. Alternatively, each time an interlayer insulating layer included in the insulating film is formed, a groove for separation may be formed by patterning the interlayer insulating layer, thereby forming the insulating film that comprises interlayer insulating layers having a continuous groove for separation. Both methods can easily provide an insulating film having the separation groove on the dicing line region.

After forming the wiring layers and interlayer insulating layers, a protection film, such as a silicon nitride film, is formed on the resultant structure. The protection film may be provided to cover the test pads and marks or not to cover them.

Although in the example shown in FIG. 2, each separation groove continuously extends around the corresponding element-forming region, it may extend intermittently around the region. FIGS. 11 and 12 show examples of intermittently extending separation grooves. In the example of FIG. 11, rectangular separation grooves 4 are formed around the element-forming region at regular intervals. Further, in the example of FIG. 12, L-shaped separation grooves 4 are provided around the corners of the element-forming region. When a blade is moved over a semiconductor wafer to make a cut thereon, the L-shaped separation grooves as shown in FIG. 12 protect the vulnerable corners of the insulating film located at the corners of the element-forming region. As shown in FIG. 12, the provision of the L-shaped separation grooves at the corners of the element-forming region greatly increases the protection.

Referring to FIG. 13, a second embodiment of the invention will be described.

FIG. 13 is a plan view of a semiconductor wafer according to the second embodiment, illustrating an insulating film provided on a dicing line region. As in the first embodiment, test pads formed of Al or Cu and used for testing the state of each element-forming region in the wafer stage are formed on the dicing line region. These test pads are connected, by conductive wires, to to-be-tested integrated circuits, such as semiconductor elements, provided on the element-forming regions. Where separation grooves are formed as in the first embodiment, the conductive wires are exposed at the separation grooves. In this state, the wires may be easily damaged by an external force.

In light of this, in the second embodiment, no separation groove is provided and an insulating film remains at a location at which a conductive wire is provided. Accordingly, each separation groove does not completely surround the corresponding element-forming region. The conductive wire 26 is covered with the portion 27 of the insulating film 26, therefore are not damaged by an external force.

Referring to FIG. 13, a semiconductor wafer 20 has a plurality of element-forming regions 21, and a dicing ling region 22 that separate the element-forming regions 21 from each other. Test pads 23 and positioning marks 23′ are provided on the portion of an insulating film 35 located on the dicing line region 22. The test pads 23 are connected, by conductive wires 26, to the semiconductor elements provided on the element-forming regions.

The insulating film 25 covers the element-forming regions 31 and dicing line region 32. Like the insulating film shown in FIG. 3, the insulating film 25 is formed of multi-layered insulating layers which insulate respective wiring layers of a multi-layer form. Further, separation grooves 24 that separate the dicing line region 32 from the element-forming regions 34 are formed in the portion of the insulating film 25 located on the dicing line region 22.

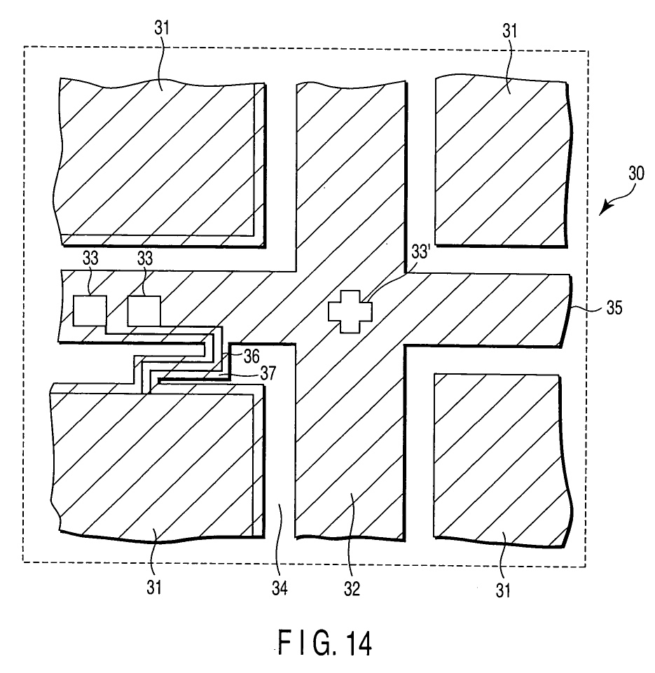

Referring to FIG. 14, a third embodiment of the invention will be described.

FIG. 14 is a plan view of a semiconductor wafer according to the third embodiment, illustrating an insulating film provided on a dicing line region. As in the first embodiment, test pads formed of Al or Cu and used for testing the state of each element-forming region in the wafer stage are formed on the dicing line region. These test pads are connected, by conductive wires, to to-be-tested integrated circuits, such as semiconductor elements, provided on the element-forming regions. Where separation grooves are formed as in the first embodiment, the conductive wires are exposed at the separation grooves. In this state, the wires may be easily damaged by an external force.

In light of this, in the third embodiment, no separation groove is provided and an insulating film remains at a location at which a conductive wire is provided. Accordingly, each separation groove does not completely surround the corresponding element-forming region. Further, in the third embodiment, the conductive wires are made long in the dicing region. To make the wires long, the wires are formed in a zigzag manner.

Referring to FIG. 14, a semiconductor wafer 30 has a plurality of element-forming regions 31, and a dicing ling region 32 that separate the element-forming regions 31 from each other. Test pads 33 and positioning marks 33′ are provided on the portion of an insulating film 35 located on the dicing line region 32. The test pads 33 are connected, by conductive wires 36, to the semiconductor elements provided on the element-forming regions. Unlike the second embodiment, the wires 36 extend in a zigzag manner on the dicing line region 32. This zigzag wiring absorbs the force exerted, in a dicing process, upon the insulating film 35 on the element-forming regions 31. The zigzag portions of the conductive wires 36 are covered with the portion 37 of the insulating film 36, therefore are not damaged by an external force.

The insulating film 35 covers the element-forming regions 31 and dicing line region 32. Like the insulating film shown in FIG. 3, the insulating film 35 is formed of multi-layered insulating layers which insulate respective wiring layers of a multi-layer form. Further, separation grooves 34 that separate the dicing line region 32 from the element-forming regions 34 are formed in the portion of the insulating film 35 located on the dicing line region 32.

With above-described embodiments, the insulating film on the element-forming regions is prevented from being peeled off in a dicing process, even if the insulating film is a low-dielectric-constant insulating film having low mechanical and adhesion strengths.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor wafer comprising:
a plurality of element-forming regions;
a dicing line region which separates the element-forming regions from each other; and
an insulating film which covers the element-forming regions and the dicing line region, the insulating film being formed of multi-layered insulating layers which insulate respective wiring layers of a multi-layer form,
wherein a separation region is formed at least in a portion of the insulating film located on the dicing line region, the separation region separating the insulating film on the dicing line region from the insulating film on the element-forming regions.

2. The semiconductor wafer according to claim 1, wherein the insulating film is a low-dielectric-constant insulating film.

3. The semiconductor wafer according to claim 2, wherein the low-dielectric-constant insulating film has a relative dielectric constant of less than 3.9.

4. The semiconductor wafer according to claim 1, wherein the separation region comprises a region surrounding each of the element-forming regions.

5. The semiconductor wafer according to claim 4, wherein a separation groove is formed in the separation region.

6. The semiconductor wafer according to claim 1, wherein the separation region comprises a region surrounding entire peripherals of each of the element-forming regions.

7. The semiconductor wafer according to claim 6, wherein a separation groove is formed in the separation region.

8. The semiconductor wafer according to claim 1, wherein the separation region comprises a plurality of separation regions provided along peripherals of each of the element-forming regions.

9. The semiconductor wafer according to claim 8, wherein separation grooves are formed in the separation regions.

10. The semiconductor wafer according to claim 1, wherein the separation region comprises a plurality of separation regions provided at corners of each of the element-forming regions.

11. The semiconductor wafer according to claim 10, wherein separation grooves are formed in the separation regions.

12. The semiconductor wafer according to claim 1, wherein the dicing line region has at least one test pad, the test pad being provided on a predetermined one of the element-forming regions and connected to a conductive wire connected to a semiconductor element formed on the predetermined one element-forming region, the conductive wire being covered with the insulating film.

13. The semiconductor wafer according to claim 12, wherein the conductive wire extends in a zigzag manner on the dicing line region.

14. A method of producing a semiconductor wafer, comprising:
forming a plurality of element-forming regions separated from each other by a dicing line region, the element-forming regions each having a semiconductor element;
covering the element-forming regions and the dicing line region with an insulating film, the insulating film being formed of multi-layered insulating layers which insulate respective wiring layers of a multi-layer form; and
forming a separation region at least in a portion of the insulating film located on the dicing line region, the separation region separating the insulating film on the dicing line region from the insulating film on the element-forming regions.

15. A method of producing a semiconductor wafer, according to claim 14, wherein the separation region is formed using chemical etching.

16. The method of producing a semiconductor wafer according to claim 14, wherein, in forming the insulating film having the separation region formed therein, patterning, each time one of the interlayer insulating layers is formed, the one interlayer insulating layer to form a region for separation in the one interlayer insulating layer, and repeating the patterning to form the insulating film with the separation region in a form of a continuous region formed of the regions for separation.

17. A semiconductor chip comprising:
an element-forming region in which a semiconductor element is formed;
a dicing line region which surrounds the element-forming regions; and
an insulating film which covers the element-forming region and the dicing line region, the insulating film being formed of multi-layered insulating layers which insulate respective wiring layers of a multi-layer form,
wherein a separation region is formed at least in a portion of the insulating film located on the dicing line region, the separation region separating the insulating film on the dicing line region from the insulating film on the element-forming region.

18. The semiconductor chip according to claim 17, wherein the insulating film is a low-dielectric-constant insulating film.

19. The semiconductor chip according to claim 18, wherein the low-dielectric-constant insulating film has a relative dielectric constant of less than 3.9.

20. The semiconductor chip according to claim 17, wherein the separation region comprises a region surrounding the element-forming region.
